(19) United States
(12) Patent Application Publication
(10) Pub. No.: US 2007/0249143 A1
(43) Pub. Date: Oct. 25, 2007

(54) Method and device of manufacturing thin substrate

(76) Inventor: Hiroshi Ido, Ibaraki (JP)

Correspondence Address: BIRCH STEWART KOLASCH & BIRCH, PO BOX 747, FALLS CHURCH, VA, 22040-0747, US

(21) Appl. No.: 11/785,540

(22) Filed: Apr. 18, 2007

(30) Foreign Application Priority Data
Apr. 19, 2006 (JP) 2006-115609

(51) Int. Cl. H01L 21/30

(52) U.S. Cl. 438/459

(57) ABSTRACT

An easy and low-cost method of manufacturing a thin substrate reduced in surface wobbling by bonding two thin sheets together is provided. A step of bonding thin substrate sheets together is performed by using a device in which a spacer is incorporated into a turntable provided with a through-hole for air inflow. The thin substrate sheets are rotated on the turntable, to spin off and cure an adhesive for bonding.

### BACKGROUND OF THE INVENTION

1. Field of the Invention

The present invention relates to a method and a device of manufacturing a thin substrate used as a material of an optical recording medium and the like, and more particularly to a method and a device of manufacturing a thin substrate by bonding two thin sheets together.

2. Description of Related Art

In recent years, various attempts have been made in order to increase capacity of an optical disk. Among the attempts, increasing the capacity per volume by reducing the thickness of an optical disk substrate attracts attention as an efficient method. For example, JP-A-2003-91970 proposes a recording/reproducing system in which recording capacity per volume is increased by combining a thin optical disk and a stabilizer for stably rotating the thin optical disk with less surface wobbling.

On the other hand, if the substrate of the optical disk is a single plate, the substrate significantly deforms due to the bimetal effect, and therefore, there has been the problem that it lacks reliability as an information recording medium. In order to cope with this, conventionally, it is popular to manufacture an optical disk having a vertically symmetrical structure by bonding two substrates together. As for the above described thin optical disk, the manufacturing method of bonding two thin sheets together is adopted. For example, JP-A-2000-048419 and JP-A-2005-216426 propose an art of bonding thin sheets together while holding the thin sheets flatly by spraying air.

Further, as another art of bonding optical disk substrates together, there is known the method of forming a multilayer film by means of the 2P method (photo-curing method). For example, JP-A-09-161329 proposes an art of spreading a resin used for the 2P method on a substrate, and rotating the substrate to spin off the resin for curing.

### BRIEF SUMMARY OF THE INVENTION

However, the above described manufacturing methods by bonding the optical disk substrates together have the problem of being incapable of using a spin-coat device or the like conventionally used, and therefore requiring a special device. Further, as will be described later, it became clear from experiments by the present inventors that the thin optical disk manufactured by the art of bonding the substrates together such as the 2P method does not have sufficient surface wobbling characteristics and surface wobbling acceleration characteristics.

The present invention is made in view of the above circumstances, and provides a method and a device of manufacturing a thin substrate by bonding two thin sheets together, which are easy and at low cost, and reduce surface wobbling of the thin substrate.

In view of the above problems to be solved, the present inventors have searched for a method capable of manufacturing a thin substrate reduced in surface wobbling at low cost by using a conventional spin coat device.

First, the inventors have additionally prepared a turntable for supporting the thin substrate in a conventionally used spin coat device, and repeated various experiments by placing the thin substrate on the turntable. However, the thin substrate shows the behavior differing from that of a conventional thick substrate, and therefore it was difficult to produce a thin substrate favorable in surface wobbling characteristics and surface wobbling acceleration characteristics by bonding. The inventors have found out that this is because the thin substrate itself has low rigidity and tends to have static electricity, and tried to improve that.

The inventors has placed the thin substrate of a thickness of about 100 μm on the turntable made of aluminum with substantially the same diameter as the thin substrate, and tried to support the thin substrate on the turntable. As a result, the following phenomena have appeared.

(a) The turntable and the thin substrate adhere to each other only in a partial region thereof.

(b) It is observed that the adhered portion involves other portions successively so that the adhered region becomes expanded.

(c) However, the expansion of the adhered region stops in a certain range, and the adhered region does not expand any more.

(d) Eventually, the turntable and the thin substrate do not adhere to each other uniformly, and air entrainment portions remain here and there.

(e) When bonding is performed while leaving the air entrainment portions as it is, the surface wobbling can not be reduced.

In view of the above facts, the inventors have considered that the air entrainment phenomenon is the cause of inhibiting the surface wobbling acceleration, confirmed the reason why the air entrainment phenomenon occurred, and thought out a method of avoiding it. First, the inventors paid attention to the phenomenon in which the above described adhered portions are always generated locally. Then, the inventors paid attention to the fact that the thin substrate is made of a nonconductor, and found out that static electricity is concerned in the phenomena. When electrostatically charged portions are contact with each other to neutralize the static electricity of these portions, the adhered portion does not expand any more, so that the adhered portions are generated locally corresponding to the electrostatically charged portions. As a result of this, since distortion partially occurs in the thin substrate, excess and deficiency occur in the region of the portions which have not neutralized, so that island portions, which have been left while not being adhered to each other, remain. The inventors have considered that the air entrainment phenomenon occurs for such a reason. Concerning the surface wobbling acceleration, the inventors have considered that the above described air entrainment which locally appears causes the surface wobbling especially at a high frequency, instead of the sine-wave low frequency surface wobbling as seen in a conventional thick substrate, and this worsens the surface wobbling acceleration. If bonding of the thin substrates and curing of the adhesive are performed while air entrainment is not removed, the air entrainment is directly transferred onto the thin substrate and remains there semipermanently, and it becomes very difficult to remove it in a subsequent process.

In order to solve the above described problems, in a method and a device of manufacturing a thin substrate of the present invention, a spacer is assembled in the vicinity of the center of a turntable. Further, the turntable in which a hole for air inflow is provided is used. A through-hole is directly provided in a doughnut plate constituting the turntable. As described above, by providing the spacer, a gap is ensured between the thin substrate and the turntable, and through the gap, air is introduced from the through-hole for air inflow at the time of rotating the turntable. The spacer is constituted by a rigid body, a top surface contacted with the thin substrate and a bottom surface contacted with the turntable are parallel with each other, and the height between the top surface and the bottom surface is constant.

That is, the present invention provides a method of manufacturing a thin substrate by bonding two thin substrate materials together, which method includes the steps of disposing one thin substrate material on a rotatable turntable so that a spacer is put therebetween, coating an adhesive on the thin substrate material, overlaying another thin substrate material on the above described thin substrate material, and curing the adhesive by rotating the turntable. The turntable preferably has a through-hole provided in the vicinity of an inner periphery thereof, and is further preferably characterized by including a plurality of the through-holes which are disposed circumferentially to be symmetrical about the center of rotation of the turntable.

The method of manufacturing a thin substrate according to the present invention is characterized in that inner peripheral portions of the two thin substrate materials are bonded together by thermocompression bonding. For example, a hot melt sheet or the like is used therefor.

The method of manufacturing a thin substrate of the present invention is characterized in that, the thin substrate is manufactured on the condition of:

2×t×1.03<T<2×t×1.10

where T is the thickness of the thin substrate to be manufactured, and t is the thickness of each of the thin substrate materials.

The present invention also provides a device for manufacturing a thin substrate by bonding two thin substrate materials together, which device includes a rotatable turntable for holding the thin substrate material, a spacer disposed in the vicinity of an inner periphery between the thin substrate material and the turntable, a clamp for fixing the thin substrate material and the spacer to the turntable, a means for applying an adhesive to the thin substrate material on the turntable, a means for overlaying the other thin substrate material onto the thin substrate material on the turntable, and a means for curing the adhesive applied on the thin substrate material on the turntable while rotating the turntable.

The device for manufacturing a thin substrate of the present invention is characterized in that a diameter of the turntable is substantially the same as that of the thin substrate material, or smaller by 5% or less than that of the thin substrate material. By adopting this constitution, it is possible to prevent the adhesive from flowing into between the thin substrate and the turntable during spin-coating of the adhesive.

As described above, according to the method and the device of manufacturing a thin substrate of the present invention, it is possible to manufacture a thin substrate reduced in surface wobbling, easily and at low cost, by bonding two thin sheets together.

### BRIEF DESCRIPTION OF THE SEVERAL VIEWS OF THE DRAWINGS

FIG. 1 is a view showing one embodiment of a method of manufacturing a thin substrate of the present invention;

FIG. 2 is a view showing another embodiment of the method of manufacturing a thin substrate of the present invention;

FIG. 3 is a flow chart showing process of manufacturing a thin substrate by using the equipment shown in FIG. 1;

FIG. 4 is tables exemplifying the conditions of spin coating in the manufacturing process of a thin substrate;

FIG. 5 is a view schematically showing the construction of a spin coat device used in an example;

FIG. 6 is diagrams showing a method of bonding a clamp area in an inner peripheral portion of a flexible sheet;

FIG. 7 is a diagram showing displacement results of one round of the substrate at the radius position of 40 mm of a thin substrate which is produced in the example and a thin substrate which is produced by a conventional method;

FIG. 8 is a diagram showing results of measuring surface wobbling acceleration at the radius position of 57 mm at the time of rotation of substrates, with respect to the thin substrate which is produced in the example and the thin substrate which is produced by the conventional method;

FIG. 9 is a diagram showing results of measuring the surface wobbling acceleration at the radius position of 40 mm at the time of rotation of substrates, with respect to the thin substrate which is produced in the example, and the thin substrate which is produced by the conventional method; and

FIG. 10 is a diagram showing results of measuring the surface wobbling acceleration at the radius position of 27 mm at the time of rotation of substrates, with respect to the thin substrate which is produced in the example, and the thin substrate which is produced by the conventional method.

### DETAILED DESCRIPTION OF THE INVENTION

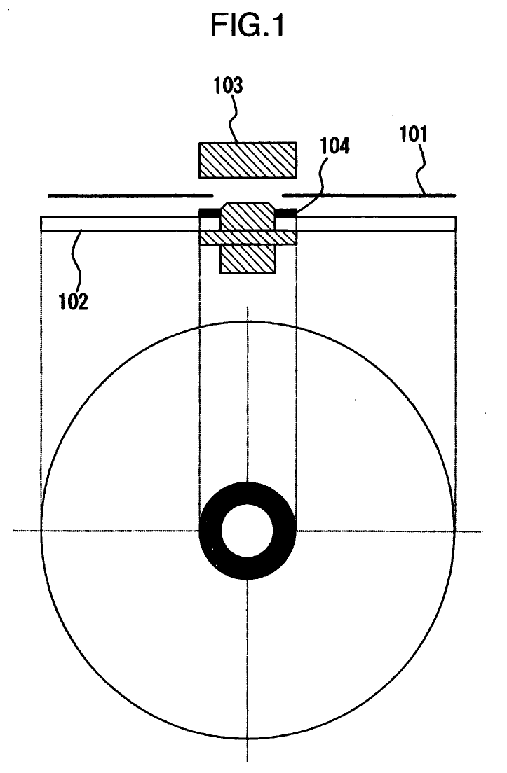

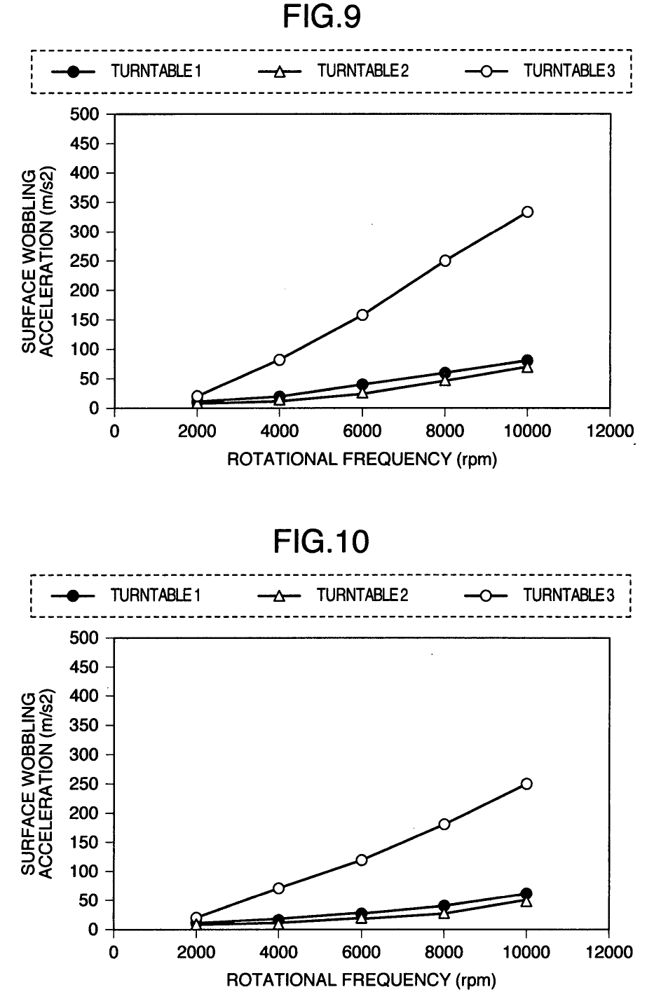

The best mode for carrying out a method and a device of manufacturing a thin substrate of the present invention will now be described in detail with reference to the attached drawings. FIGS. 1 to 9 are the drawings illustrating embodiments of the present invention, and in these drawings, the parts assigned with the same reference numerals and characters represent the same components, and the basic constructions and operations thereof are similar.

FIG. 1 is a view showing one embodiment of the method of manufacturing a thin substrate of the present invention. As shown in FIG. 1, it is the processes of disposing a flexible sheet 101 on a turntable 102, fixing it with a clamp 103, rotating the turntable 102 to spin off an adhesive and to bond sheets together. A spacer 104 for lifting up an inner peripheral portion of the flexible sheet 101 from its downside is disposed on an inner peripheral portion of the turntable 102. The flexible sheet 101 is held by being sandwiched by the upper clamp 103 and the lower spacer 104. The spacer 104 ensures a gap between the flexible sheet 101 and the turntable 102.

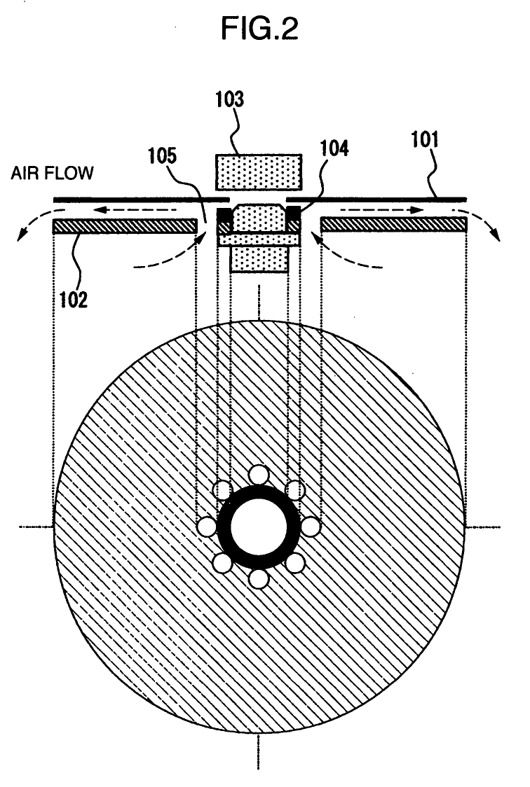

FIG. 2 is a view showing another embodiment of the method of manufacturing a thin substrate of the present invention. As shown in FIG. 2, it is the processes of disposing the flexible sheet 101 on the turntable 102, fixing it with the clamp 103, rotating the turntable 102 to spin off an adhesive and to bond sheets together. A spacer 104 for lifting up the inner peripheral portion of the flexible sheet 101 from the downside is disposed on the inner peripheral portion of the turntable 102. The flexible sheet 101 is held by being sandwiched by the upper clamp 103 and the lower spacer 104. Through-holes 105 for air inflow are formed in the vicinity of an inner periphery of the turntable 102.

When the turntable 102 is rotated in this state, air in the gap between the flexible sheet 101 and the turntable 102 moves by a centrifugal force from the inner periphery to an outer periphery beginning at the vicinity of an outer peripheral end of the spacer 104, and further, a steady-state air flow from the inner periphery to the outer periphery is generated by the air flowing into the gap from the through-hole 105. By the features, the local air entrainment phenomena caused by static electricity at the stationary time are totally removed. The space between the flexible sheet 101 and the turntable 102 made by the spacer 104 is usually desired to be 0.01 to 0.5 mm.

The through-hole 105 for air inflow may be provided in a doughnut-shaped plate itself of the turntable, and alternatively, it may be provided in a hub mounted concentrically to the center of the doughnut-shaped plate of the turntable. Since this makes air flow smoother, local surface wobbling can be reduced and a stable state with less surface wobbling can be kept. By uniformly providing a number of through-holes 105, a uniform air flow can be realized. In practice, a plurality of, preferably, 3 to 50 through-holes are desired to be disposed circumferentially to be symmetrical about the center of rotation. The diameter of the through-hole 105 is desirably 2 mm to 7 mm. However, the diameter and the number of the through-holes 105 are limited such that the strength of the turntable 102 does not become extremely low. While it is not shown in the drawing, the peripheral edge of the through-hole 105 is desired to be annealed so that an eddy is not generated or the substrate is not damaged due to the existence of the through-hole 105.

With respect to the turntable 102, by making the outside diameter the same as the outside diameter of the flexible sheet 101, or smaller by 5% or less than the outside diameter of the flexible sheet 101, the adhesive can be prevented from flowing into between the flexible sheet 101 and the turntable 102 on the occasion of spin-coating of the adhesive.

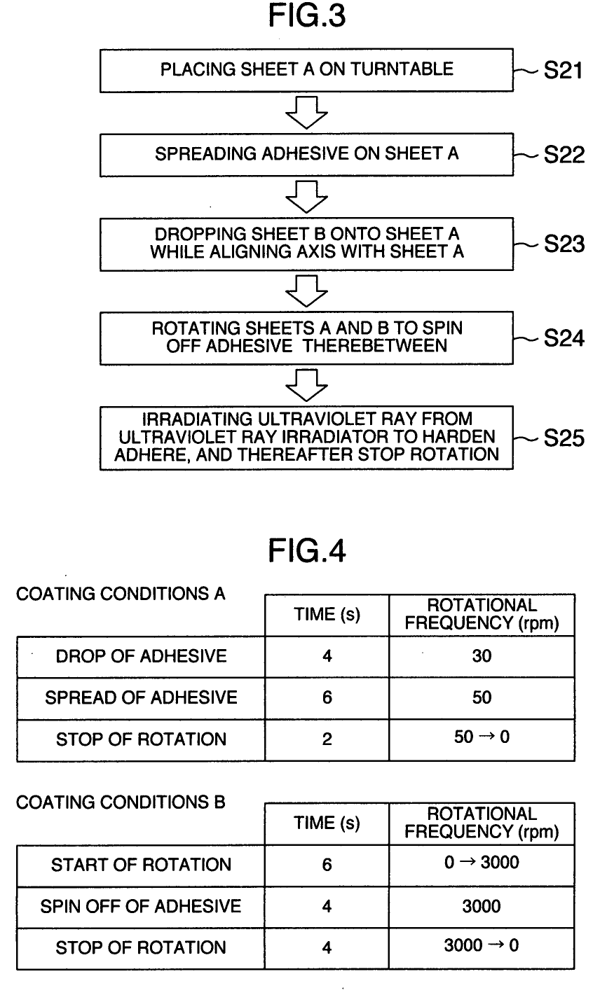

Next, the processes of manufacturing a thin substrate by using the equipment shown in FIG. 1 or 2 will be described with reference to FIG. 3. In FIG. 3, first, a flexible sheet A is set on the turntable 102 (step S21). An adhesive is applied onto the flexible sheet A, and the turntable 102 is rotated to spread the adhesive under predetermined coating conditions (for example, the coating conditions A shown in FIG. 4) (step S22). Subsequently, a flexible sheet B is overlaid thereon while aligning its center axis with that of the flexible sheet A on the turntable 102 (step S23). The turntable 120 is rotated to spin off the adhesive between the flexible sheets A and B under predetermined coating conditions (for example, the coating conditions B shown in FIG. 4). Thereafter, an ultraviolet ray is irradiated to the flexible sheets A and B by using an ultraviolet ray irradiating device to cure the adhesive, and then the rotation of the turntable 102 is stopped (step S25).

By the above processes, it is possible to manufacture the thin substrate according to the present invention which is enhanced in surface wobbling characteristics and surface wobbling acceleration characteristics. Hereinafter, more concrete example will be described.

### EXAMPLE

A polycarbonate film having a thickness of 100 μm, an inside diameter of 15 mmφ and an outside diameter of 120 mmφ is prepared, and grooves and pits of DVD-R specifications are formed by a nanoimprint device made by Nanonics Corporation. Next, a dye recording layer, and a metal alloy reflection layer containing silver as a main constituent are stacked by 15 nm to produce two flexible sheets capable of optical recording and reproduction. As a turntable, an aluminum circular plate having a thickness of 1 mm, an inside diameter of 15 mmφ and an outside diameter of φ119 mm is prepared (this is defined as “a”), and in addition to this, the turntable on which eight inflow through-holes each of 6 mmφ are equidistantly disposed in a circumferential form at positions of 18 mm from the center was prepared (this is defined as “b”). Further, a spacer made of SUS304 with an outside diameter of 30 mmφ, an inside diameter of 15 mmφ and a thickness of 0.2 mm is prepared. In the following, the turntable on which the above described spacer and the above described “a” are concentrically fixed respectively is called a turntable 1, the turntable on which the above described spacer and the above described “b” are concentrically fixed respectively is called a turntable 2, and the turntable on which only the above described “a” is fixed is called a turntable 3.

The turntable used in this example is made of soda glass, but is more enhanced in effect by performing the following treatment. (1) Forming a nitride silicon or oxide silicon thin film of 1 nm or more on the soda glass. (2) Roughening the soda glass surface to have a mesh size of #6000 or smaller, more preferably #1000 or smaller. Alternatively, forming a very fine recessed and projected shape with 1 mm pitch or less. The treatment (1) mainly has the effect of reducing charged static electricity between the polycarbonate which is the material of the thin substrate and the turntable, and the treatment (2) mainly has the effect of enabling an air layer to readily enter between the thin substrate and the turntable. The above described treatments (1) and (2) may be individually used respectively, but by using those in combination, a larger effect can be exhibited.

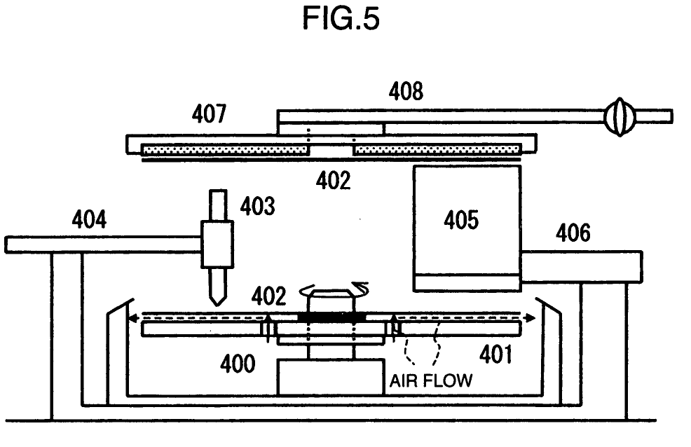

FIG. 5 is a view schematically showing the construction of the spin coat device used in this example. In FIG. 5, this spin coat device is constituted by a rotary base 400, a turntable 401, a syringe 403, a syringe moving and supporting mechanism 404, an ultraviolet ray irradiator 405, an ultraviolet ray irradiator moving and supporting mechanism 406, a vacuum chuck 407 and a vacuum chuck supporting and moving mechanism 408. A center rod of the rotary base 400 is used for aligning the eccentricity of the flexible sheets, which are to be overlaid, with each other. In order to pass through a center hole of φ15.05 mm (±0.02) of the flexible sheet, the center rod is made to be φ15.1 mm (±0.02), and has a tip end of a tapered cone shape so as to readily pass through the hole. The vacuum chuck 407 is made by porous ceramics made by Nippon Tungsten, Co., Ltd., and can be switched to an adsorption side and an ejector side by switching a valve. The syringe 403 is a device for dropping an ultraviolet curing adhesive (SD318 made by DAINIPPON INK AND CHEMICALS, INCORPORATED is used in this example) onto the flexible sheet while regulating its drop amount.

Hereinafter, the procedure for bonding the flexible sheets together by this spin coat device will be described. First, one flexible sheet 402 is held by the vacuum chuck 407, and is disposed on the turntable 401 from above the spin coat device. Hereinafter, the flexible sheet is called a sheet A. Next, by the syringe 403, the ultraviolet curing adhesive is dropped onto the position of the inner periphery (r=18 to 23 mm) of the sheet A, and the adhesive is spread up to about r=35 mm in accordance with the coat conditions A shown in FIG. 4. Namely, the adhesive is dropped for 4 seconds at the rotational frequency of 30 rpm, and then, the rotational frequency is set at 50 rpm to spread the adhesive on the substrate for 6 seconds. Finally, the rotation is stopped within 2 seconds.

Next, another flexible sheet (hereinafter, called a sheet B) is disposed so as to be overlaid on the sheet A on the turntable 401 by the vacuum chuck 407. A magnet clamp (not shown) is disposed from above the sheets A and B, and the adhesive between the sheets A and B is spun off in accordance with the coat conditions B shown in FIG. 4, whereby uneven thickness of the adhesive does not occur in the inner peripheral portion and the outer peripheral portion of the sheet. Namely, the rotational frequency is increased up to 3000 rpm for 6 seconds, and held at 3000 rpm for 4 seconds, and finally the rotation is stopped within 4 seconds.

Next, ultraviolet irradiation is applied to the bonded sheets using the ultraviolet ray irradiator 405, so that the adhesive is cured. When the adhesive is cured, the rotation of the turntable 401 is stopped, and the clamp is removed. When curing the adhesive, in order to make both surfaces of the bonded sheets uniform, it is preferable to irradiate one of the surfaces with ultraviolet irradiation intensity such that the one surface is cured in the order of about 30 to 70%, and thereafter, apply ultraviolet irradiation to the other surface by an amount of making up for a deficiency. Thereby, substrate deformation caused by a heat ray, and imbalance in the curing degree can be reduced, and therefore, a thin substrate with less surface wobbling can be obtained.

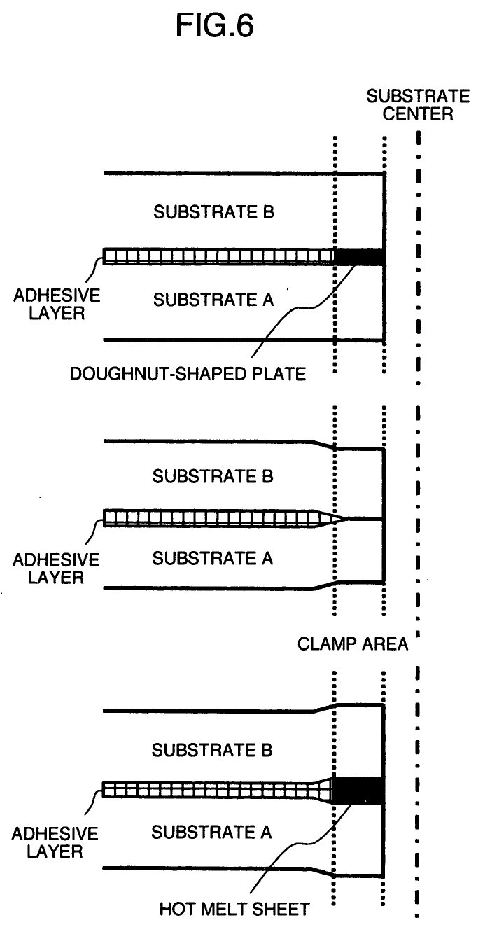

In the above described process, the adhesive layer is formed between the two flexible sheets each having a substrate thickness of 100 μm. Thereby, the thin substrate which is 210 μm thick at the inner periphery (r=20 mm), and 215 μm thick at the outer periphery (r=58 mm) has been produced. When the two flexible sheets are held with the magnet clamp, the clamp with an outside diameter of φ20 is used, and therefore, the adhesive layer is formed up to about r=10 mm which corresponds to the clamp outside diameter, while at the outer periphery, the adhesive layer is formed up to the substrate outermost periphery of r=60 mm by the spinning off process. Here, since the adhesive does not reach the above described clamp area, the two flexible sheets are bonded by any one of the following three kinds of methods as shown in FIG. 6.

(1) Polyethylene terephthalate, polyethylene naphthalate or polycarbonate which is cut into a doughnut shape of a thickness of 25 μm with an outside diameter of φ9 and an inside diameter of φ7.5 is prepared, and this is sandwiched between a substrate A and a substrate B at the time of bonding (see an upper diagram in FIG. 6).

(2) Ultraviolet irradiation or corona discharge treatment is performed only in the above described clamp area in advance to increase the surface energy, and further, thermocompression bonding (temperature of 140 degrees, pressure of 1 t) is performed only in the treated regions to bond the thin substrates together (see a central diagram in FIG. 6).

(3) Hot melt sheet (model 3100; thickness of 30 μm, melting point of 130 degrees) made by DAICEL FINE CHEM LTD. which is additionally prepared is cut into the shape with the outside diameter of φ9 and the inside diameter of φ7.5, and this is sandwiched between the substrate A and the substrate B at the time of bonding. After the bonding layer is formed, the inner peripheral portions of the substrate A and the substrate B are bonded via the above described hot melt sheet by thermocompression bonding (temperature of 140 degrees, pressure of 1 t) (see a lower diagram in FIG. 6).

Note that the above described various conditions are nothing but examples, and the kind of adhesive and the forming conditions of the bonding layer are not limited to these. Concerning the thickness (called T) of the completed thin substrate in the information area, as long as the thickness T is in the following range:

2×(t)×1.03<T<2×(t)×1.10

where the thickness of the original flexible sheet is set as t, the same effect as in this example can be obtained.

If the outside diameter of the turntable is made larger than the outside diameter of the thin substrate in the above described process, the adhesive flows into between the turntable and the thin substrate in the process of spinning off the adhesive. When the outside diameter of the turntable becomes smaller than the outside diameter of the thin substrate by 5% or more, wobbling of the substrate at the outer peripheral portion during rotation, that is, during formation of the bonding layer becomes especially large. Therefore, the distortion amount of the outer peripheral portion of the thin substrate which is completed also becomes remarkably large as a result. Accordingly, the outside diameter of the turntable is desirably the same as or smaller by 5% than the outside diameter of the thin substrate.

The thin substrate produced in this example (turntables 1 and 2) and the thin substrate produced by a conventional manufacturing method (turntable 3) are prepared, and their performances are compared.

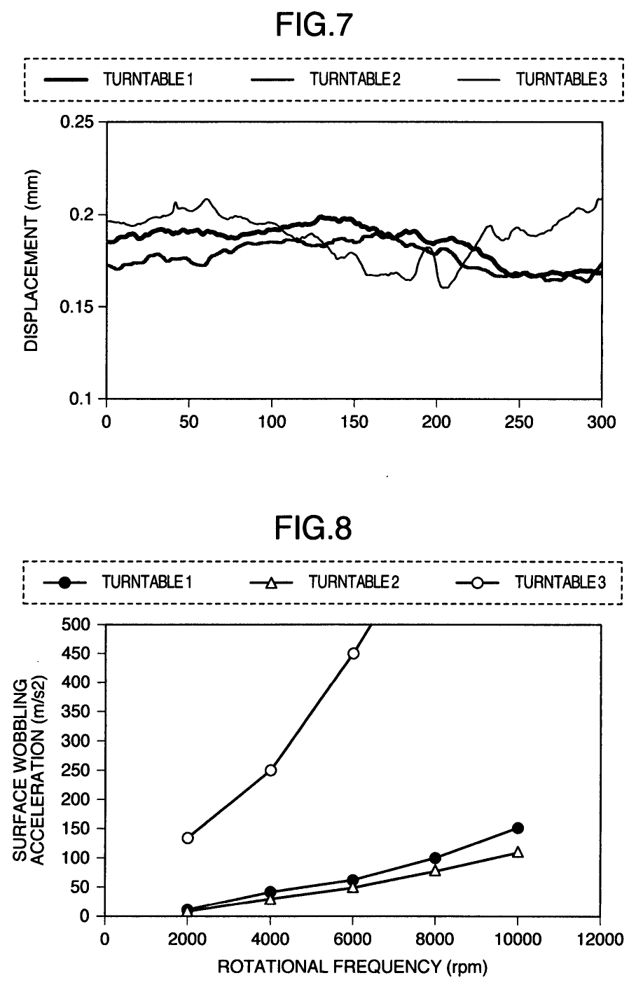

First, with respect to these two kinds of thin substrates, the substrate displacements in a static state are measured by a CCD laser displacement meter made by Keyence Corporation which is additionally prepared. FIG. 7 shows the displacement result of one round of the substrate at the radius position of 40 mm. Large displacement changes are seen in the thin substrate according to the conventional manufacturing method here and there, but displacement change is hardly seen in the thin substrate according to the manufacturing method of this example. Namely, it is found out that the characteristic local displacement remains in the thin substrate according to the conventional manufacturing method, but such local displacement does not exist in the thin substrate of this example.

Next, concerning the above described two kinds of thin substrates, the surface wobbling acceleration at the time of rotation of the substrate is measured by using the laser Doppler meter made by Sony Corporation. FIGS. 8 to 10 are diagrams respectively showing the results of measuring the surface wobbling accelerations at the radius positions of 57 mm, 40 mm and 27 mm on the substrate. As is obvious from each of the diagrams, it is found out that the surface wobbling acceleration becomes dramatically lower in the thin substrate according to the manufacturing method of this example than the thin substrate according to the conventional method in any radius position at any rotational frequency. As shown in, for example, FIG. 8, while the surface wobbling acceleration at 5000 rpm at the radius position of 57 mm is 350 m/s² in the thin substrate of the conventional manufacturing method, in the thin substrate according to the manufacturing method of this example, the surface wobbling acceleration is dramatically improved to 60 M/s². This shows that the specifications of DVD-R8× is satisfied, and it is sufficiently shown that the manufacturing method of this example is effective in reducing the surface wobbling of the thin substrate which is completed.

The method and device of manufacturing the thin substrate of the present invention are described by showing the concrete embodiments thus far, but the present invention is not limited to those. A person skilled in the art can add various modifications and improvements to the construction and function of the invention according to the above described embodiments or other embodiments within a range which departs from the spirit of the present invention.

1. A method of manufacturing a thin substrate by bonding two thin substrate materials together, comprising the steps of:
disposing one thin substrate material on a rotatable turntable so that a spacer is sandwiched therebetween, the turntable comprising a through-hole formed therein;
applying an adhesive onto the thin substrate material;
overlaying another thin substrate material on said thin substrate material; and
curing the adhesive by rotating the turntable.

2. A method of manufacturing a thin substrate by bonding two thin substrate materials together, comprising the steps of:
disposing one thin substrate material on a rotatable turntable so that a spacer is sandwiched therebetween, the turntable comprising a through-hole formed therein;
applying an adhesive onto the thin substrate material;
overlaying another thin substrate material on said thin substrate material; and
curing the adhesive by rotating the turntable, wherein
the rotatable turntable comprises a plurality of said through-holes, which are arranged in a circumferential direction to be symmetrical about the rotation center of the turntable.

3. The method according to claim 1, further including the step of bonding inner peripheral portions of the two thin substrate materials together by means of thermocompression bonding.

4. The method according to claim 2, further including the step of bonding inner peripheral portions of the two thin substrate materials together by means of thermocompression bonding.

5. The method according to claim 1, wherein the thin substrate is manufactured to satisfy the following expression:
2×t×1.03<T<2×t×1.10
where T is the thickness of the thin substrate to be manufactured, and t is the thickness of each of the thin substrate materials.

6. The method according to claim 2, wherein the thin substrate is manufactured to satisfy the following expression:
2×t×1.03<T<2×t×1.10
where T is the thickness of the thin substrate to be manufactured, and t is the thickness of each of the thin substrate materials.

7. The method according to claim 1, wherein the thin substrate is manufactured by adjusting the amount of an adhesive layer so that surface wobbling acceleration of the thin substrate is 100 m/s² or less at a rotational frequency of 8000 rpm or less.

8. The method according to claim 2, wherein the thin substrate is manufactured by adjusting the amount of an adhesive layer so that surface wobbling acceleration of the thin substrate is 100 m/s² or less at a rotational frequency of 8000 rpm or less.

9. A device for manufacturing a thin substrate by bonding two thin substrate materials together, comprising:
a rotatable turntable for holding the thin substrate material, the turntable comprising a through-hole formed therein;
a spacer disposed in the vicinity of an inner periphery between the thin substrate material and the turntable;
a clamp for fixing the thin substrate material and the spacer to the turntable;
a means for applying an adhesive onto the thin substrate material on the turntable;
a means for overlaying the other thin substrate material onto the thin substrate material on the turntable; and
a means for curing the adhesive applied onto the thin substrate material on the turntable while rotating the turntable.

10. A device for manufacturing a thin substrate by bonding two thin substrate materials together, comprising:
a rotatable turntable for holding the thin substrate material, the turntable comprising a through-hole formed therein;
a spacer disposed in the vicinity of an inner periphery between the thin substrate material and the turntable;
a clamp for fixing the thin substrate material and the spacer to the turntable;
a means for applying an adhesive onto the thin substrate material on the turntable;
a means for overlaying the other thin substrate material onto the thin substrate material on the turntable; and
a means for curing the adhesive applied onto the thin substrate material on the turntable while rotating the turntable, wherein
the rotatable turntable comprises a plurality of said through-holes, which are arranged in a circumferential direction to be symmetrical about the rotation center of the turntable.

11. The device according to claim 9, wherein the diameter of the turntable is approximately the same as that of the thin substrate material, or smaller than that of the thin substrate material by 5% or less.

12. The device according to claim 10, wherein the diameter of the turntable is approximately the same as that of the thin substrate material, or smaller than that of the thin substrate material by 5% or less.
